(19) United States
(12) Patent Application Publication
(10) Pub. No.: US 2006/0248414 A1
(43) Pub. Date: Nov. 2, 2006

(54) Method and system for BitMap Analysis System for high speed testing of memories

(76) Inventor: Prashant Dubey, Ghaziabad (IN)

Correspondence Address: HOGAN & HARTSON LLP, ONE TABOR CENTER, SUITE 1500, 1200 SEVENTEENTH ST, DENVER, CO, 80202, US

(21) Appl. No.: 11/392,250

(22) Filed: Mar. 29, 2006

(30) Foreign Application Priority Data
Mar. 31, 2005 (IN) 711/DEL/2005

(51) Int. Cl. G11C 29/00

(52) U.S. Cl. 714/718

(57) ABSTRACT

A Bit Map Analysis System (BMAS) for high-speed memory testing. The BMAS reduces the amount of data transaction between the BIST and tester may be used in embedded memories, whether asynchronous or synchronous, static or dynamic, or volatile or non-volatile. The tester clock cycle is substantially reduced, resulting in reduced diagnostic process time. The BMAS operates by partitioning a memory core into a plurality of smaller segments of equal size, sequentially generating bitmaps for the smaller segments, and storing the generated bitmaps for each of the smaller segments in a first-in-first-out (FIFO) memory segment that is equivalent to the size of the smaller segments. The BMAS also transmits the generated bitmaps to a tester using a serial pipe of predetermined size from the FIFO based on the tester clock.

### RELATED APPLICATION

The present application claims priority of India Patent Application No. 711/Del/2005 filed Mar. 31, 2005, which is incorporated herein in its entirety by this reference.

### FIELD OF INVENTION

The present invention relates to a Bit Map Analysis System (BMAS) for high-speed testing of memories.

### BACKGROUND OF THE INVENTION

The semiconductor industry has intensified its focus on yield issues to meet the challenges of manufacturing devices at sub-nanometer and below. An important step in correcting the existing manufacturing yield issues is finding the defects. For this reason, an important component of a comprehensive test methodology is effective embedded memory testing. Relative to logic circuitry, the redundant nature of a memory structure makes it easier to pinpoint locations of defects, in many cases down to specific transistors.

Recent technology advances in memory built-in-self-test (BIST) have made it the most prevalent methodology for testing embedded memories, and, for BIST, bitmap or failure map is important. Thus, if somehow, a snapshot of the core is taken then by seeing the pattern of the snapshot one can make inferences about the faults present in the address decoder, or Input Output (I/O), or core. This snapshot is known as the Bitmap and is generated by writing some known data on the memory and then reading and comparing each word to see which word location or bit location is failing. This is the raw information used to create the bit map. In FIG. 1, a Bit Map of a memory is been shown.

There are several problems that are commonly encountered while generating the bitmap. It is observed that more faults occur at high clock speeds for reading/writing from memories. However, most testers today operate at a very low clock speed as the I/O's for the testers fail at high frequencies. Due to this problem, many faults that should be detected may be missed. The raw data for one word is normally of a good length as it contains the address of the word, the data output of the memory, and the stimuli which were written. Sometimes if the test is running at the tester's frequency, the stimuli and the address information can be left out as by counting the number of clock cycles at which the fault occurred, and one can tell the address and the stimuli. In addition, if the test patterns were run through a tester, there is no need of the address and stimuli information. The data output response of the memory itself is enough. However, sometimes this information is also big and it takes a lot of space to store it as well as to send it out to the tester. The channels through which the tester receives the data are far smaller in number, and normally, only one output is available to pipe the data serially out.

All widely used current methodologies for testing memories treat the memory blocks as macros, and hence, all the faults whether they are in the address decoder or I/O or core of the memory are finally mapped on the core.

Some of the devices used for generating the Bit Map of the embedded memories are as follows:

Serial Pipe Based:

FIG. 2 shows the block diagram for this type of methodology. A memory core 20 is connected to a BIST 21 having Fail Counter 22 and Serial Pipe 23. In this kind of methodology, whenever a fault occurs, the faulty address information is transferred to a single word pipe 23. The Built In Self-Test (BIST) 21 sends a flag to the tester to gather the faulty address information. Until all the bits have been read by the tester, the BIST 21 is kept on hold. In addition, the frequency of operation in this case is very low as the BIST 21 runs at the speed of the tester frequency. In case of a number of faults, even if the BIST 21 runs at a high frequency, the BIST 21 wait time will make the test run at a low speed test. This is not an effective technique. This process takes a long time, and extra software and resources are required in the tester to generate a bitmap of the memory.

Parallel First-in-First-out (FIFO) Memory Based Bitmap Generator:

This method is an extension to the serial pipe based method. In this method instead of using a serial pipe of one word 23 as shown in FIG. 1, a Serial Pipe of N words is used. In this method, a FIFO is added to the structure, which stores the information of the failing word each time the fault occurs. The FIFO works on the BIST clock. In parallel, the information is transferred to the tester using the serial pipe, which shifts the information at the tester's clock. The advantage of using a FIFO is to interface a fast BIST with a slow tester. The drawbacks of this method are that no matter how big a FIFO is used, one can never stop the BIST from waiting for the tester to read the complete information once the FIFO stack is full. Thus, FIFO stack height can never be decided with surety. In addition, the raw information to be stored is again very big. Thus, considerable area and time is consumed in this method, and all the efforts of generating a high-speed bit map of the memory are wasted if the stack is full and the BIST has to wait.

Fail Counter Method:

In this kind of Bit Map generation method, the BIST stops each time during the run when it encounters a fault. Every time the BIST stops, it stores all the raw information about the fault and sends it to the tester and increments the fail counter. In its next run, the BIST stops at the N+1th fault where N is the current value of the counter. Thus, one can generate the bit map with all the information given by the BIST. The problem with this methodology is that this counter is unused if there are very few faults. In addition, if there are a large number of faults, then one needs a very big counter. Also this method needs a lot of time and hardware resources to generate the complete bit map of the memory. In addition, the method does not generate good information in case of marginal errors where the error occurs in one run, and it does not repeat itself in the next run, thus the BIST skips a genuine fault due to this deficiency.

Compression-based methods are another set of techniques that are used to generate a bitmap of a faulty memory. A problem with these methods is that the compression is always lossy; hence, the complete picture is not obtained for the memory. In addition, the hardware needed for compression takes a lot of area, which is not suitable for production units where the bitmap is only needed in case of debugging at the early stage of the Integrated Circuit (IC) product.

Hence, the disadvantages of existing architectures are as follows:
The existing architectures are unable to generate bit map at very high speed.
The time taken is very long, especially for the fail counter method.
The transferred information is not a full bit map of the memory under test but raw information, which has to be processed to get the bitmap at the tester end.
The size of the internal FIFO is insufficient, and the BIST may stop in the middle of the test to prevent the overflow of FIFO buffer in case of fast occurring faults.
The bit map generated may give wrong information in case of marginal errors.
Some faults may get undetected in case of the fail counter method, as the March elements of the algorithm are never completely run.
If the raw information is compressed on chip then the compression is lossy as well as unsuitable for random memory address testing through BIST.

The present invention provides a bit map analysis methodology with a unique architecture, which solves the problems created by the above-mentioned disadvantages. The new architecture has a low area overhead and the device is aimed at providing a faster execution of the diagnostic process.

### SUMMARY OF THE INVENTION

To obviate the aforesaid drawbacks, an object of the instant invention is to provide a bit map analysis with low area overhead.

Another object of the invention is to reduce the amount of data transaction between the BIST and the tester.

Yet another object of the invention is to reduce the tester clock cycles, due to which the diagnose timings are reduced drastically.

To achieve the aforesaid and other objects, the instant invention provides a Bit Map Analysis System for high-speed memory testing of memory partitioned into small, equal-sized memory segments. The system includes a test engine connected to the memory for generating bitmaps, and a First In First Out (FIFO) memory mechanism having its write port connected to the test engine and its read port connected to a tester. The FIFO memory mechanism contains at least one FIFO memory segment equivalent to the size of said memory segments. The test engine sequentially generates and verifies the bitmaps of each of said memory segment.

A serial pipe of predetermined size is also provided that is connected to the read port of said FIFO mechanism for reading and transmitting the test results. In a preferred embodiment, the memory core is partitioned into equal sized segments.

The test engine of the present invention may preferably include a state machine connected to the FIFO mechanism and a tester for controlling and managing the handshake signals, a Built-in-Self-Test (BIST) connected to the state machine for generating bitmap for the memory core and FIFO, a first counter connected to the state machine for counting up to total Bits/N, a second counter connected to the state machine for counting up to total Words/M, a programmable read address sequence generator (PRASG) serially interfaced to the tester for providing address sequence generation.

A method of the present invention for high speed testing of memory includes the steps of partitioning a memory core into smaller equal sized segments, sequentially generating bitmaps for the memory segments, storing the bitmap result of each memory segment in a FIFO memory segment equivalent to the size of the memory segments after being extracted for analysis before generating the bitmap for next memory segment. Preferably, the stored results are transmitted to a tester using a serial pipe of predetermined size.

The solution provided through BMAS strategy is worth using inside the embedded memories whether they are asynchronous or synchronous, static or dynamic, volatile or non-volatile. This invention reduces the amount of data transaction between the BIST and the tester. Hence, the tester clock cycle reduces drastically, resulting in reduced diagnostic process time.

### BRIEF DESCRIPTIONS OF THE DRAWINGS

The present invention is described with the help of accompanying drawings:

FIG. 1 shows a Bit Map of the memory.

FIG. 2 shows the prior art.

FIG. 3 illustrates the block diagram showing the BMAS.

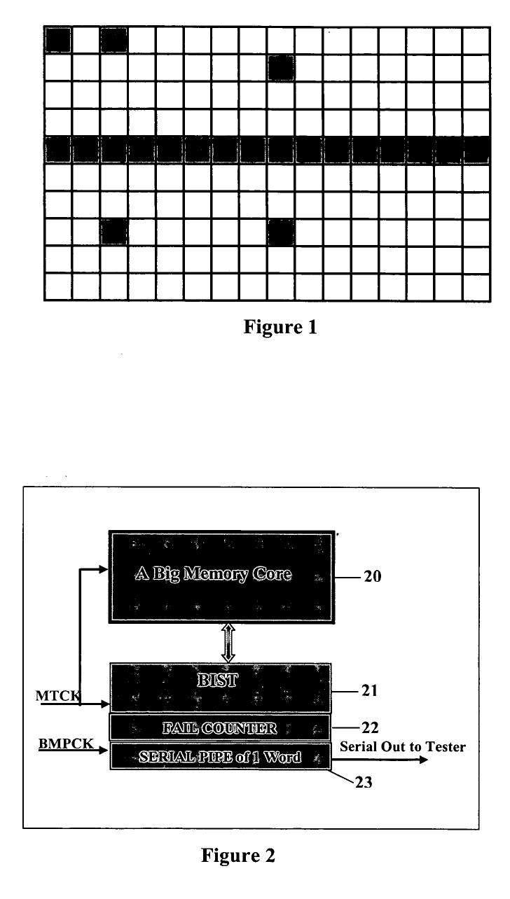

### DETAIL DESCRIPTION OF THE INVENTION

In the current approach of analyzing memory faults and creating a bitmap, a FIFO is used as an interface between a BIST and a tester. The invention divides a big memory core into many small logical memory cores and generates a bit map for the same that can be stored in a smaller FIFO.

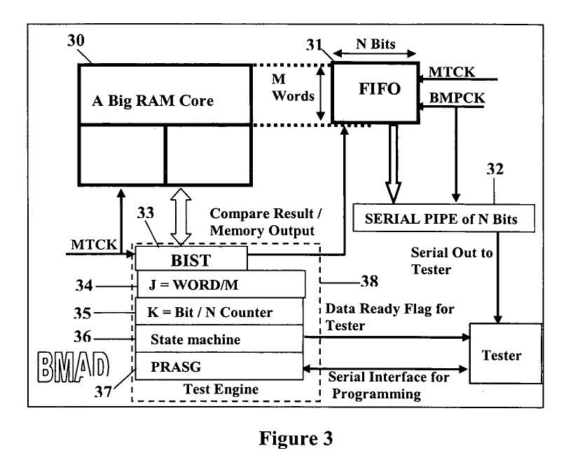

FIG. 3 shows a block diagram of an embodiment of a Bit Map Analysis System (BMAS) of the invention. It contains a RAM core 30, BIST 33 that contains the March Element Opcode Loader and is linked to RAM core 30, a FIFO 31 with M words and N data bits connected to a Serial Pipe 32 to convert N bits to 1-bit information per tester clock. The embodiment also includes a counter 34 which counts up to (Total Words)/M, a counter 35 which counts up to (Total Data Bits)/N, a state machine 36 to organize all the activities and manage the handshake signals with the tester and a Programmable Read Address Sequence Generator (PRASG) 37 for configuring the address sequence from tester through a serial interface.

OPCODE LOADER: It is generally a sequence of instructions run by the BIST 33 and is a combination of various March elements. Any March element is further a combination of some write or read operations. Thus, a March element forms a complete stimulus, by which one can tell, what operations have been done on the memory and what can be the expected data. Thus, the opcode loader loads the background data to be written as well as the expected data to be taken for each FIFO 31, in terms of inverted or non-inverted data background. The data background is sent only once at the beginning of the instructions and remains constant for all the March elements. Only the expected inverted data or non-inverted data as well as the number of operations in one March element change with each new March element. This reduces the need to transfer the stimuli along with the bitmap. Thus, the expected data bitmap at the tester can be formed.

FIFO: The FIFO 31 is used to represent a part of the RAM core 30. The write port is connected to the BIST 33 while the read part is connected to the tester. Thus, BIST 33 writes into the first word of the FIFO 31 when it makes the first valid measurement. If the result of the memory word is false, it stores logic 1 in place of that bit, otherwise logic 0 is stored. This activity is repeated until all the words in the current window are over. As the BIST 33 does not stop during one March element run, the number of parallel FIFOs needed is equal to the number of maximum operations in any of the March elements.

STATE MACHINE: As soon as the FIFO 31 is full, the state machine 36 generates a flag for the tester to start reading the bitmap. BIST 33 runs for all the possible windows, one by one. As soon as the FIFO 31 is full, the state machine 36 sends a signal to the tester to read the stored bitmap of the current window. In addition, the BIST 33 continues to run the March element until all the words of the memory 30 are exhausted. At the last word of the memory 30, the BIST 33 waits for the tester to complete reading of the FIFO 31. Once all the data has been read, the state machine 36 starts the BIST 33 from beginning of the March element of interest and makes the comparison accordingly.

PRASG: The PRASG 37 is the block that generates the address on which the read operation is performed on the ROM core 30. The sequence generated can be a pseudo random pattern, which can be programmed by reseeding at the beginning of the memory test. The deterministic sequence can be programmed up to K number of read cycles per address, where the address sequence can be defined for M number of words for each read cycle.

COUNTERS: The counters 34 and 35 are used to run the BIST 33 for as many times as there are possible windows. The number of runs required is obtained by dividing the number of words in the memory by the number of words in the FIFO 31 chosen.

SERIAL PIPE: The serial pipe 32 is the interface in the parallel domain of the BIST 33 and the serial domain of the tester. If there are more pins that can be dedicated for the debug and diagnostics purposes, one can reduce the length of the serial pipe 32. The clock of the serial pipe 32 is that of the tester clock speed.

An approach or exemplary operation of the system of FIG. 3 is as follows:
1. A FIFO is used with N data bits and M words.
2. BIST runs at a high-speed clock and the faults are generated.
3. Thus, each time the BIST runs a March element, it runs on the whole memory, but the memory output is only compared for M number of words and N number of data bits each time. The result of the comparison is stored in the FIFO with M words of N word length.
4. The comparison response is stored for all the M words and the N bits in the window, and either they fail or do not fail. This creates the complete bitmap of the window for a given March element run.
5. When one March element has been completed, the BIST stops and sends a signal to the tester. Thus, the tester reads the complete bitmap of the M words and N bits of the memory under test, which is stored in the FIFO.
6. When the whole data has been stored in the tester, the tester gives a restart signal to the BIST.
7. The BIST runs from the beginning of the March algorithm currently active and compares for the next set of M words and N bits in the same March element as previous.
8. BIST continues this way until the same March element has been run for all the possible windows of M words and N bits in the memory.
9. After that, it runs the same for the next March element in the March algorithm by taking each time or step the next M words and N bits only.

Thus, at the end of this operation or testing process, the tester has the complete bitmap of the memory. In addition, the stimuli need not be stored along with the faulty bit information stored on chip. The stimulus is known to the tester. The bitmap has to be different for each comparison of the same word. Thus, if there are k read/write operations to be done in one March element on the BIST and where out of k, only x one operations will be measured by the BIST, x identical FIFOs are needed for one set of bitmap data.

While there have been described above the principles of the present invention in conjunction with specific memory architectures and methods of operation, it is to be clearly understood that the foregoing description is made only by way of example and not as a limitation to the scope of the invention. Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The applicants hereby reserve the right to formulate new claims to such features and/or combinations of such features during the prosecution of the present application or of any further application derived therefrom.

We claim:

1. A Bit Map Analysis System (BMAS) for high-speed memory testing of memory partitioned into small, equal-sized memory segments, comprising:
a test engine connected to said memory for generating bitmaps; and
a First In First Out (FIFO) memory mechanism having its write port connected to said test engine and its read port connected to a tester, said FIFO memory mechanism containing at least one FIFO memory segment equivalent to the size of said memory segments,
wherein said test engine sequentially generates and verifies the bitmaps of each of said memory segments.

2. A BMAS as claimed in claim 1, wherein a serial pipe of predetermined size is connected to the read port of said FIFO memory mechanism for reading and transmitting test results.

3. A BMAS as claimed in claim 1, wherein said memory comprises a RAM core partitioned into equal sized segments.

4. A BMAS as claimed in claim 1, wherein said test engine comprises:
a state machine connected to said FIFO mechanism and said tester for controlling and managing handshake signals; and
a Built-in-Self-Test (BIST) connected to said state machine for generating the bitmaps for said memory and said FIFO.

5. A BMAS as claimed in claim 4, wherein said test engine further comprises:
a first counter connected to said state machine for counting up to total Bits/N;
a second counter connected to said state machine for counting -up to total Words/M; and
a programmable read address sequence generator (PRASG) serially interfaced to said tester for providing the address sequence generation.

6. A method for high speed testing of memory, comprising:
partitioning a memory core into a plurality of smaller segments of equal size;
sequentially generating bitmaps for said smaller segments; and
storing said generated bitmaps for each of said smaller segments in a first-in- first-out (FIFO) memory segment equivalent to the size of said smaller segments after each of the smaller segments are extracted for analysis and before generating a bitmap for a next one of the smaller segments.

7. A method for high speed testing of memory as claimed in claim 6, wherein stored generated bitmaps are transmitted to a tester using a serial pipe of predetermined size.

8. A system for high speed testing memory, comprising:
means for accessing a memory core, wherein the memory core is partitioned into two or more segments of equal size;
a memory mechanism comprising a segment equivalent in size to the memory core segments; and
a test engine generating a bitmap for one of the memory core segments and storing the bitmap into the segment of the memory mechanism.

9. The system of claim 8, wherein the segment of the memory mechanism comprises a FIFO mechanism.

10. The system of claim 9, wherein a write port of the memory mechanism is connected to the test engine.

11. The system of claim 9, further comprising a tester connected to a read port of the memory mechanism.

12. The system of claim 11, further comprising a serial pipe of predetermined size providing an interface between the tester and the memory mechanism, wherein the FIFO mechanism operates based on a clock of the tester.

13. The system of claim 8, wherein the test engine sequentially generates additional bitmaps for each of the memory core segments and wherein the memory mechanism comprises additional segments of size matching the memory core segment size for storing the additional bitmaps.

14. The system of claim 13, wherein the test engine verifies the bitmaps of each of the memory core segments.

15. The system of claim 14, wherein the test engine comprises a Built In Self Test (BIST) mechanism.
